(19) United States
(12) Patent Application Publication
(10) Pub. No.: US 2025/0350284 A1
(43) Pub. Date: Nov. 13, 2025

(54) SEMICONDUCTOR DEVICE, MEMORY SYSTEM INCLUDING DUTY CYCLE CORRECTION CIRCUIT AND OPERATION METHOD THEREOF

(71) Applicant: SK hynix Inc., Gyeonggi-do (KR)

(72) Inventor: Ho Youn CHOI, Gyeonggi-do (KR)

(21) Appl. No.: 19/087,605

(22) Filed: Mar. 24, 2025

(30) Foreign Application Priority Data
May 10, 2024 (KR) 10-2024-0061865
Dec. 30, 2024 (KR) 10-2024-0200109

(51) Int. Cl. H03L 7/081; G11C 16/32; H03K 5/156

(52) U.S. Cl. CPC H03L 7/0812; G11C 16/32; H03K 5/1565

(57) ABSTRACT

A semiconductor device includes a delay locked loop (DLL) configured to output a first correction value corresponding to a single cycle of a clock and a duty correction circuit including a divider configured to divide the clock in half to generate a divided clock, delay the divided clock by a delay value corresponding to a half cycle of the clock to generate a delayed clock, and generate an adjusted clock having a duty ratio of 5:5 based on the divided clock and the delayed clock. The delay value is adjusted or changed based on the first correction value.

### CROSS-REFERENCE TO RELATED APPLICATIONS

This patent application claims the benefit of priority under 35 U.S.C. § 119(a) to Korean Patent Applications Nos. 10-2024-0061865 and 10-2024-0200109, filed on May 10, 2024 and Dec. 30, 2024, the entire disclosures of which are incorporated herein by reference.

### TECHNICAL FIELD

Various embodiments of the present disclosure described herein relate to a memory system, and more particularly, to a semiconductor device or a memory system including a duty cycle correction circuit and an operation method for the semiconductor device or the memory system.

### BACKGROUND

A data processing system including a memory system or a data storage device has been developed to store more voluminous data in the data storage device and store data more quickly in the data storage device, and read data stored in the data storage device more quickly. The data storage device can include non-volatile memory cells and/or volatile memory cells for storing data. In an input and output (input/output) (I/O) interface scheme that transfers data in synchronization with a clock frequency, such as data transmission between a memory device and a memory controller in the memory system, accurate temporal synchronization between a clock and data might be requested as loads on a bus (or a data path) increases and a frequency of the data transmission increases.

### BRIEF DESCRIPTION OF THE DRAWINGS

The description herein makes reference to the accompanying drawings wherein like reference numerals refer to like parts throughout the figures.

FIG. 1 illustrates a data processing apparatus according to an embodiment of the present disclosure.

FIG. 2 illustrates a first training procedure according to an embodiment of the present disclosure.

FIG. 3 illustrates a second training procedure according to an embodiment of the present disclosure.

FIG. 4 illustrates a first clock duty control circuit according to an embodiment of the present disclosure.

FIG. 5 illustrates a second clock duty control circuit according to an embodiment of the present disclosure.

FIG. 6 illustrates an operation method for a clock duty control circuit according to an embodiment of the present disclosure.

FIG. 7 illustrates a third clock duty control circuit according to an embodiment of the present disclosure.

### DETAILED DESCRIPTION

Various embodiments of the present disclosure are described below with reference to the accompanying drawings. In this disclosure, elements and features may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational, e.g., is not turned on nor activated. Examples of block/unit/circuit/component used with the “configured to” language include hardware, circuits, memory storing program instructions executable to implement the operation, etc. Additionally, “configured to” can include a generic structure, e.g., generic circuitry, that is manipulated by software and/or firmware, e.g., an FPGA or a general-purpose processor executing software to operate in a manner that is capable of performing the task(s) at issue. “Configured to” may also include adapting a manufacturing process, e.g., a semiconductor fabrication facility, to fabricate devices, e.g., integrated circuits that are adapted to implement or perform one or more tasks.

As used in this disclosure, the term ‘machine,’ ‘circuitry’ or ‘logic’ refers to all of the following: (a) hardware-only circuit implementations such as implementations in only analog and/or digital circuitry and (b) combinations of circuits and software and/or firmware, such as (as applicable): (i) to a combination of processor(s) or (ii) to portions of processor(s)/software including digital signal processor(s), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘machine,’ ‘circuitry’ or ‘logic’ applies to all uses of this term in this application, including in any claims. As a further example, as used in this application, the term ‘machine’, ‘circuitry’, or ‘logic’ also covers an implementation of merely a processor or multiple processors or a portion of a processor and its (or their) accompanying software and/or firmware. The term ‘machine’, ‘circuitry’, or ‘logic’ also covers, for example, and if applicable to a particular claim element, an integrated circuit for a storage device.

As used herein, the terms ‘first’, ‘second’, ‘third’, and so on are used as labels for nouns that they precede, and do not imply any type of ordering, e.g., spatial, temporal, logical, etc. The terms ‘first’ and ‘second’ do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term ‘based on’ is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

Embodiments of the present disclosure can provide an apparatus and a method for transferring and receiving an electrical signal such as data, addresses, and commands within a memory system.

Further, an embodiment of the present disclosure can provide a memory device, a memory system including a memory device, a controller included in a memory system, or a data processing device including a memory system, which is configured to transfer and receive an electrical signal.

An embodiment of the present disclosure can provide a device and method that adaptively compensates for a change in a clock duty due to a difference caused by a process skew during a manufacturing process and a change in a temperature and a voltage that occurs during use of a semiconductor device, a memory device, or a memory system, thereby maintaining a constant duty ratio (e.g., 5:5) of a clock in a change in an operating environment.

In an embodiment of the present disclosure, a semiconductor device can include a delay locked loop (DLL) configured to output a first correction value corresponding to a single cycle of a clock; and a duty correction circuit configured to divide the clock in half to generate a divided clock, delay the divided clock by a delay value corresponding to a half cycle of the clock to generate a delayed clock, and generate an adjusted clock having a duty ratio of 5:5 based on the divided clock and the delayed clock. The delay value can be adjusted based on the first correction value.

The delay locked loop can be configured to detect a delay of the clock within the semiconductor device based on at least one of changes in an operational environment of the semiconductor device, including power supply and temperature, and changes in a manufacturing process, and to output the first correction value corresponding to the single cycle of the clock.

The duty correction circuit can include a divider configured to select one of a rising edge of a falling edge of the clock such that an output value of the divider transitions from a logic high level to a logic low level or from the logic low level to the logic high level based on a selected edge.

The duty correction circuit can include a first delay unit including N number of delay elements, where N is a positive integer, wherein each of the delay elements has a delay value corresponding to 1/N of the single cycle of the clock. The first delay unit can be configured to delay the divided clock by a delay element selected from among the N number of delay elements based on a half of the first correction value.

The duty correction circuit can include a first inverter configured to invert the divided clock and transfer an inverted and divided clock to the first delay unit.

The first delay unit can be configured to determine the delay value corresponding to a value obtained by subtracting a delay value of the first inverter from a half of the first correction value.

The duty correction circuit can include a first logic gate configured to perform an exclusive OR (XOR) operation on the divided clock, and the delayed clock; a second inverter configured to invert an output of the first logic gate; and a multiplexer configured to selectively output one of the output of the first logic gate and an output of the second inverter.

The duty correction circuit can further include a second delay unit configured to delay an output of the multiplexer based on a second correction value of the delay locked loop and output a delayed output.

The semiconductor device can further include a fixed value filter configured to calculate an average value for first correction values continuously output from the delay locked loop and transmit the average value to the first delay unit.

The fixed value filter can be configured to calculate the average value for values belonging to a preset deviation among the first correction values.

In another embodiment, a memory system can include at least one memory device; and a controller coupled to the at least one memory device and configured to adjust a duty ratio of a clock to generate an adjusted clock when power is supplied and perform a read or write training based on the adjusted clock. The controller can include a delay-locked loop (DLL) configured to output a first correction value corresponding to a single cycle of the clock; and a duty correction circuit configured to divide the clock in half to generate a divided clock, delay the divided clock by a delay value corresponding to a half cycle of the clock to generate a delayed clock, and generate an adjusted clock having the duty ratio of 5:5 based on the divided clock and the delayed clock.

The delay value of the first delay unit can be adjusted or changed based on the first correction value output from the delay locked loop.

The delay locked loop can be configured to detect a delay of the clock within the memory system based on at least one of changes in an operational environment of the memory system, including power supply and temperature, and changes in a manufacturing process, and to output the first correction value corresponding to the single cycle of the clock.

The duty correction circuit can include a divider configured to select one of a rising edge and a falling edge of the clock such that an output value of the divider transitions from a logic high level to a logic low level or from the logic low level to the logic high level based on a selected edge.

The duty correction circuit can include a first delay unit including N number of delay elements, where N is positive integer, wherein each of the delay elements has a delay value corresponding to 1/N of the single cycle of the clock. The first delay unit can be configured to delay the divided clock by a delay element selected from among the N number of delay elements based on a half of the first correction value.

The duty correction circuit can include a first inverter configured to invert the divided clock and transfer an inverted and divided clock to the first delay unit.

The first delay unit can be configured to determine the delay value corresponding to a value obtained by subtracting a delay value of the first inverter from a half of the first correction value.

The duty correction circuit can include a first logic gate configured to perform an exclusive OR (XOR) operation on the divided clock, and the delayed clock; a second inverter configured to invert an output of the first logic gate; and a multiplexer configured to selectively output one of the output of the first logic gate and an output of the second inverter.

The controller can further include a fixed value filter configured to calculate an average value for the first correction value continuously output from the delay locked loop (DLL) and transmit the average value to the first delay unit.

In another embodiment, a semiconductor device can include a delay locked loop (DLL) configured to output a first correction value corresponding to a single cycle of a clock; and a duty correction circuit, without a phase detection device for detecting a phase of the clock, configured to divide the clock in half to generate a divided clock, delay the divided clock by a delay value corresponding to a half cycle of the clock to generate a delayed clock, and generate an adjusted clock having a duty ratio of 5:5 based on the divided clock and the delayed clock.

These and other features and advantages of the invention will become apparent from the detailed description and the accompanying drawings of embodiments of the present disclosure. Embodiments will now be described with reference to the accompanying drawings, wherein like numbers reference like elements.

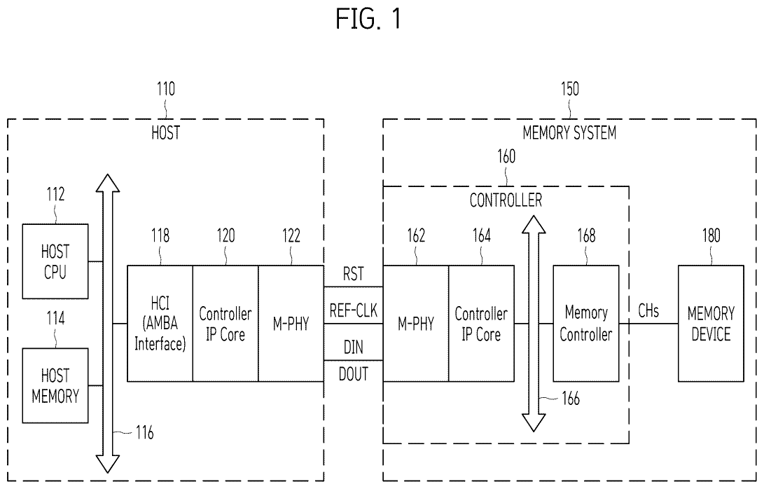

FIG. 1 illustrates a data processing apparatus according to an embodiment of the present disclosure.

Referring to FIG. 1, the data processing apparatus can include a host 110 and a memory system 150. The host 110 and the memory system 150 can include a Universal Flash Storage (UFS) electrical interface. The memory system 150 can have characteristics of a UFS memory device. The characteristics can include low power consumption, high data throughput, low electromagnetic interference, and large memory subsystem efficiency optimization. The UFS electrical interface may be based on a differential interface suggested by a Mobile Industry Processor Interface (MIPI) M-PHY specification, which establishes and supports interconnection of the UFS interface with a MIPI Unified Protocol (UniPro) specification.

According to an embodiment, the host 110 can be an entity or a device that has the characteristics of a computing device that includes one or more Small Computer System Interface (SCSI) initiator devices. The host 110 and the memory system 150 may use a predetermined set of rules or procedures for data communication or a preset interface to transmit and receive data therebetween. Examples of sets of rules or procedures for data communication standards or interfaces supported by the host 110 and the memory system 150 for sending and receiving data include Universal Serial Bus (USB), Multi-Media Card (MMC), Parallel Advanced Technology Attachment (PATA), Small Computer System Interface (SCSI), Enhanced Small Disk Interface (ESDI), United Drive Electronics (IDE), Peripheral Component Interconnect Express (PCIe or PCI-e), Serial-attached SCSI (SAS), Serial Advanced Technology Attachment (SATA), Mobile Industry Processor Interface (MIPI), and the like. According to an embodiment, the host 110 and the memory system 150 may be coupled to each other through a Universal Serial Bus (USB). The Universal Serial Bus (USB) is a highly scalable, hot-pluggable, plug-and-play serial interface that ensures cost-effective, standard connectivity to peripheral devices such as keyboards, mice, joysticks, printers, scanners, storage devices, modems, video conferencing cameras, and the like.

According to embodiments, the memory system 150 can be implemented as any of various types of storage devices such as a solid state drive (SSD), a multi-media card (MMC), an embedded MMC (eMMC), a reduced size MMC (RS-MMC), or a micro-MMC, a Secure Digital (SD) card in a form of the micro-SD, a Universal Storage Bus (USB) storage device, a Universal Flash Storage (UFS) device, a compact flash (CF) card, a Smart Media card, a Memory Stick, and etc.

The host 110 can include a host central processing unit (CPU) 112, a host memory 114, a bus interface 116, a host controller interface (HCI) 118, at least one controller IP core 120, and a physical layer (M-PHY) 122. Herein, a controller IP core can include intellectual property blocks or pre-designed and pre-verified components used or embedded in semiconductor chips or integrated circuits (ICs). The host central processing unit 112 may be capable of executing at least one application. The host memory 114 may store data to be transmitted to the host central processing unit 112 or data generated by the host central processing unit 112. The bus interface 116 may be an interface for communication between components included in the host 110. The host controller interface 118 may output or receive data to or from an external device (e.g., memory system 150) coupled to the host 110. The at least one controller IP core 120 may perform various functions such as data, command or control signal transmission, error handling, power management, and the like. The physical layer 122 may perform communication based on the MIPI M-PHY specification.

The at least one controller IP core 120 can manage and control communication between the host 110 and the memory system 150. For example, the controller IP core 120 can be used to transmit data from the host 110 to the memory system 150, and to perform operations for detecting and recovering an error occurring in data that is transmitted from the memory system 150 to the host 110.

The physical layer 122 can perform communication according to a serial communication protocol developed by the Mobile Industry Processor Interface (MIPI) organization. The physical layer 122 can be designed for high-speed data transmission used in mobile devices and other low-power devices. The physical layer 122 can be used for communication between various devices such as mobile displays, cameras, sensors, memory, etc., depending on the embodiment. In particular, the physical layer 122 can support low-power operation so that the physical layer 122 can minimize power consumption to extend a life of a battery embedded in mobile devices. In addition, the physical layer 122 can provide a high bandwidth and a fast data transmission speed via a parallel processing scheme using a multi-lane architecture, meeting the needs of high-definition video and large file transmission.

The host controller interface 118 can provide communication with the at least one controller IP core 120 and other components coupled via the bus interface 116. For example, an AMBA (Advanced Microcontroller Bus Architecture) is a bus-based communication protocol and interface developed by ARM Ltd. An AMBA interface, which includes AXI (Advanced extensible Interface), AHB (Advanced High-performance Bus), or APB (Advanced Peripheral Bus), can be used for communication between intellectual property (IP) cores in System-on-Chip (SoC) designs. The bus interface 116 can also support exchange of data or control signals between various components and the at least one controller IP core 120, which are included in the host 110.

The physical layer 122 in the host 110 can transmit or receive, to or from the memory system 150, a reset signal (RST), a reference clock (REF-CLK), input data or write data (DIN), and output data or read data (DOUT).

The memory system 150 can include a controller 160 and a memory device 180. Herein, the memory device 180 may include at least one data storage space including volatile memory cells or non- volatile memory cells.

The controller 160, which is coupled to the memory device 180 through at least one channel (CHs), can receive signals, commands, or data input from the host 110 and perform operations responsive to the signals, the commands, the data. For example, the controller 160 can store data in the memory device 180 when the data is input from the host 110. The controller 160 can transmit, to the host 110, data, which is requested by the host 110 and received from the memory device 150. The controller 160 may include a physical layer (M-PHY) 162, at least one controller IP core 164, a bus interface 166, and a memory controller 168.

The controller 160 included in the memory system 150 can include the physical layer 162 that is substantially similar to the physical layer 122 included in the host 110. The physical layer 162 may receive or transmit signals or data transmitted from or to the host 110. For example, the physical layer 162 and the physical layer 122 can operate as counter parts to each other.

According to an embodiment, the at least one controller IP core 164 in the memory system 150 can be substantially the same as the at least one controller IP core 120 in the host 110. In another embodiment, the at least one controller IP core 164 can be different from the at least one controller IP core 120. The configuration of the at least one controller IP core 164 can be determined or established in response to the bus interface 166 that supports communication between various components included in the memory system 150.

The memory controller 168 may be designed or configured based on the configuration of the memory device 180. For example, when the memory device 180 is a flash memory, the memory controller 168 may support communication with a flash memory such as a NAND or NOR device. For example, the memory controller 168 can support communication schemes and protocols set in the ONFI (Open NAND Flash Interface). The ONFI can use a data path (e.g., a channel, a way, etc.) that includes signal lines that are capable of supporting bidirectional transmission and reception of 8-bit or 16-bit data units between different components. Data communication between the controller 160 and the memory device 180 can be performed through a device that supports an interface designed for at least one scheme among asynchronous SDR (Asynchronous Single Data Rate), synchronous DDR (Synchronous Double Data Rate), and Toggle DDR (Toggle Double Data Rate).

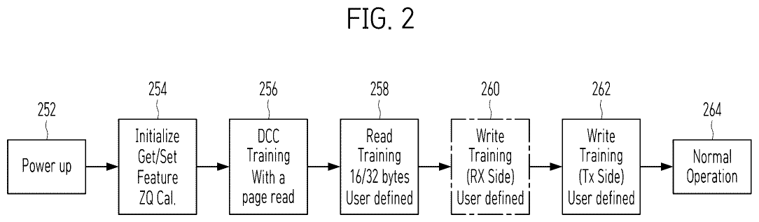

FIG. 2 illustrates a first training procedure according to an embodiment of the present disclosure. Specifically, FIG. 2 describes the first training procedure including plural operations which the controller 160 or the host 110 can sequentially perform when power is supplied. Herein the controller 160 or the host 110 can be configured to transmit and receive commands, signals, or data with the memory device 180.

Referring to FIG. 2, when power is supplied (operation 252), the controller 160 or the host 110 can initialize various information or parameters for a ZQ calibration and then set the completed information or parameters after completing the ZQ calibration (operation 254).

After the ZQ calibration (operation 254), the controller 160 or the host 110 can perform a Duty Cycle Correction (DCC) training (operation 256). The DCC training can be intended or designed to optimize input/output (I/O) performance of the memory device 180 and increase the reliability of data transmission. The DCC training is a type of technology that adjusts a duty cycle of signals (e.g., CLK, RE_t, RE_c) to improve accuracy of data transmission. The DCC training could increase the speed of data transmission from/to the controller 160 or the host 110 and reduce signal distortion of the data transmission from/to the controller 160 or the host 110.

The controller 160 or the host 110 can perform the DCC training by transmitting a signal (e.g., a preset command or an address) to the memory device 180. For example, the memory device 180 can include a function address register (e.g., Feature Address Registers) used to set and control a specific function. The function address register can include information which is preset to perform an operation to optimize operations engaged with, or performed within, the memory device 180 and to increase reliability of data transmission. The controller 160 or the host 110 can determine whether to perform a specific function (e.g., whether to activate DCCE_EN) by activating or deactivating a specific value in the function address register. After setting or activating the function, the controller 160 or the host 110 can execute a Random Data Out command with a specific address (e.g., 00h) and send a signal having a page size to compensate a signal (e.g., a phase of RE_t or RE_c). At this time, the page size can be set differently based on a manufacturer or an internal design of the memory device 180. During a data output cycle generated by the toggle of the signal (e.g., RE_t, RE_c), a control signal (e.g., DQ, DQS) being trained could be driven based on a designed scheme and implementation or could put into a high impedance (Hi-Z) state. The controller 160 or the host 110 can invalidate or ignore data exchanged or used in this training process. If signal transmission is not normally detected (e.g., a training failure), the controller 160 or the host 110 can repeat the DCC training.

After performing the DCC training 256, the controller 160 or the host 110 can perform a read training 258. The read training (or called a read DQ training) is an operation performed to adjust timing(s) of data signals (e.g., DQ) and/or control signals (e.g., DQS) to thereby increase the accuracy of data transmission in the memory device 180 and ensure reliable data transmission. For example, the memory device 180 can output a preset data pattern of 16 bits or 32 bits to each DQ pin, and the controller 160 or the host 110 can read data corresponding to a preset number of times. That is, this is an operation performed by the controller 160 or the host 110 to optimize the timing of the data signal DQ. The read training can reduce an error that might occur in a transmission while the controller 160 or the host 110 reads data from the memory device 180. Accordingly, the read training can increase the reliability of data transmission.

The controller 160 or the host 110 coupled to the memory device 180 can perform a write training (operations 260, 262). Like the read training, the controller 160 or the host 110 can perform the write training (operations 260, 262) to optimize the timing of data signals so that data to be stored in the memory device 180 could be accurately transmitted, thereby reducing an error that might occur in data transmission between the memory device 180 and the controller 160 or the host 110. Here, the write training can be divided into a transmission (Tx)-side training (operation 262) and a reception (Rx)-side training (operation 260). According to an embodiment, the reception-side training (operation 260) could be selectively or optionally performed.

After the write training (operations 260, 262), the controller 160 or the host 110 can perform normal operations (e.g., data input/output operations, etc.) with the memory device 180 (operation 264).

After power is supplied, each signal or data transmission for the various operations described above can be performed based on a clock. When transferring signals or data at high speed, the signals or the data can be transferred based on a rising edge or a falling edge of the clock.

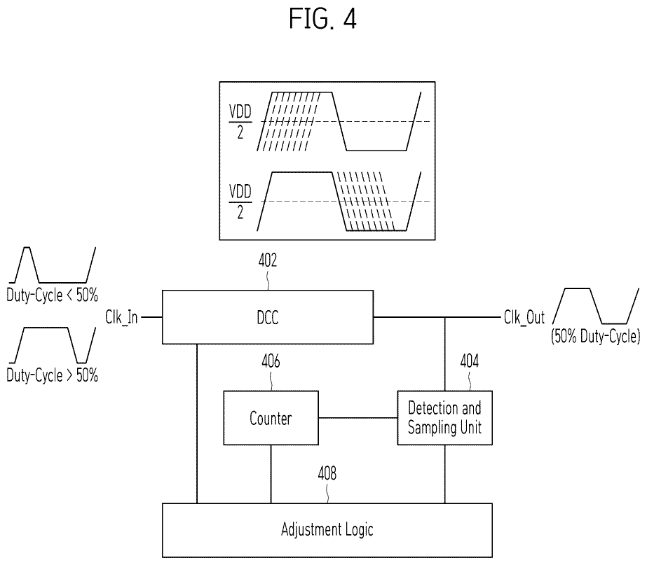

To increase the reliability of signal or data transmission, it can be a great advantage to maintain the 5:5 duty ratio of the clock as well as a constant cycle of the clock. Accordingly, the controller 160 or the host 110 can include a duty correction circuit as described in FIGS. 4 to 7.

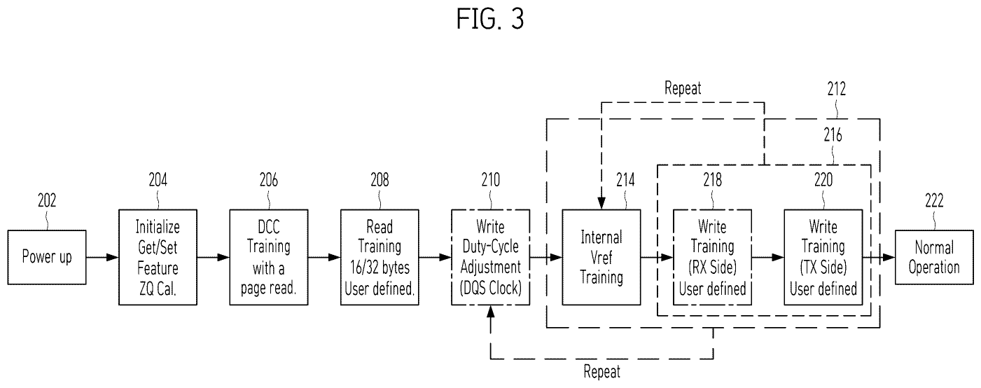

FIG. 3 illustrates a second training procedure according to an embodiment of the present disclosure. FIG. 3 describes the second training procedure performed for improving the reliability of signal or data transmission with the memory device 180 operating at high speed. For convenience, the following description may focus on an operation corresponding to a difference between the first and second training procedures shown in FIG. 2 and FIG. 3.

Referring to FIG. 3, a procedure of performing various trainings between the controller 160 and the memory device 180 is described, after the memory system 150 is powered on (operation 202).

Interface (I/F) initialization (operation 204) can include an operation performed at a relatively slow interface speed, such as high-speed interface setting, driver strength setting, ZQ calibration, etc. The interface (I/F) initialization (operation 204) can be performed before plural trainings.

Thereafter, the controller 160 can perform a DCC training (operation 206) before performing read/write DQ trainings (operations 208, 210, 212). Here, the DCC training (operation 206) can correspond to the DCC training (operation 256) described in FIG. 2. In the memory system 150, the controller 160 and the memory device 180 can be coupled through data paths, multiple channels. According to an embodiment, multiple memory chips or dies could be connected per each channel. For example, the controller 160 and the memory device 180 in the memory system 150 could be implemented in several semiconductor chips or dies. The semiconductor chip or die can perform data transmission at a speed of 3.6 Gbps or more. Accordingly, it can be very critical to maintain a duty cycle of the control signal (e.g., DQS, RE, etc.) which is likely used as a clock (CLK) between interface circuits of the controller 160 and the memory device 180. If the duty cycle of the control signal (e.g., DQS, RE, etc.) is not constantly maintained, the distortion of the duty cycle can make it impossible to guarantee the data transmission speed between the controller 160 and the memory device 180 implemented in separate chips or dies. Maintaining the duty cycle of the control signal (e.g., DQS, RE, etc.) and maintaining the duty cycle of the clock CLK can be achieved through a substantially similar manner.

A scheme for adding a buffer chip between the controller 160 and the memory device 180 has been proposed. However, projected performance might not be achieved due to the duty cycle distortion of the control signal (DQS) used as a sampling clock of the DQ data line. This duty cycle distortion can be more severe because distortion can occur inside the buffer chip rather than outside the buffer chip. Thus, to solve this issue, it can be necessary to compensate for the duty cycle of the control signals (e.g., DQS, RE) used as the clock for data latches and signal processing within the system-on-chip (SoC) or the memory system 150. In particular, the duty cycle of the clock CLK or the control signal (e.g., DQS, RE, etc.) can vary based on changes in the operating environment (e.g., power or temperature) or the manufacturing process of the controller 160 and the memory device 180. Thus, it is necessary to adjust, or compensate for, the duty cycle of the clock CLK or the control signal (e.g., DQS, RE, etc.) based on a current timing at which the memory system 150 operates.

In addition, even if data such as unmatched signals (e.g., unmatched DQS) and control signals (DQS, RE) such as clocks are transmitted at different timings (e.g., a time difference), which are supported by the memory device 180, the controller 160 and the memory device 180 can compensate for and/or delay a clock line to support a communication protocol. After duty cycle compensation or adjustment, a compensated or delayed signal output for the clock line by a certain value or more could be used for data or signal transmission.

The most important reference value used during the duty cycle restoration operations performed by a duty correction circuit (DCC) designed based on digital logic can be a value corresponding to a single cycle of a clock (e.g., a 1 cycle of 1× clock) output after an operation performed by a delay locked loop (DLL). An output value (e.g., a lock value) of the delay locked loop (DLL) can be a single cycle value during operations of the memory system 150. Because a delay element (e.g., a delay cell) included in a delay line has a delay value changed based on changes in process, voltage, and temperature (i.e., PVT variations), the output value (e.g., a lock value) of the delay locked loop (DLL) can vary based on skews and changes in temperature and voltage of the memory system 150.

According to an embodiment, to mitigate malfunction due to error in an output value (e.g., a DLL lock value) of the delay locked loop (DLL) continuously measured during the operations of a memory system 150, an average value can be calculated by a fixed value filter (e.g., lock value filter) during a predetermined time. The result (e.g., the average value) can be used to adjust a delay value in the duty correction circuit (DCC), so that the duty correction circuit (DCC) can adaptively follow changes in at least one of process, voltage and temperature (PVT) of the memory system 150 to generate or output a delayed output (e.g., a delayed clock).

Referring to FIG. 3, the read training (operation 208) can correspond to the read training described in FIG. 2, and the write training (operation 216) in the DQ training (operation 212) can correspond to the write training (operations 260, 262) described in FIG. 2.

After the read training (operation 208), the controller 160 can perform an adjustment operation for adjusting a duty of the control signal (e.g., DQS) (operation 210). Depending on changes in voltage and temperature of the memory system 150, it could be monitored whether the last obtained training setting (e.g., a training result value) is sufficient to generate a low error rate at interfaces between the controller 160 and the memory device 180. For example, a first interface training can set allowable margins of a fast section (e.g., X DAC) and a slow section (e.g., Y DAC) regarding the crossing point of the control signal (e.g., DQSn, DQS) and set a strobe point of the control signal (e.g., DQS/DQSn). When there is a trigger for monitoring the interface, the controller 160 can try to obtain a training setting that pulls in or delays the crossing point by a preset range and checks an operational status of the interface. If the result of the duty-cycle adjustment passes, the controller 160 does not need to perform an interface training again. On the other hand, if the result of the duty-cycle adjustment fails, the controller 160 can perform the interface training again.

During the write training (operation 212), the controller 160 can train a level of an internal data reference voltage (e.g., Internal VrefQ) that serves as a reference in operations of storing and reading data in the memory device 180 (operation 214). For example, the internal data reference voltage (e.g., Internal VrefQ) can be used as a reference for determining whether data stored or output in a memory cell is ‘0’ or ‘1’. When the internal data reference voltage (e.g., Internal VrefQ) is set incorrectly, an error in data could occur. The training for the internal data reference voltage (e.g., Internal VrefQ) (operation 214) could help in data stability, performance optimization, and power consumption reduction.

After the training for the internal data reference voltage (e.g., Internal VrefQ) (operation 214), the controller 160 can perform a write training (operation 216). If the writing training (operation 216) does not proceed normally, the controller 160 can perform the training for the internal data reference voltage (e.g., Internal VrefQ) (operation 214) again (Repeat).

Further, when the training (operation 212) does not proceed normally, the controller 160 can perform the adjustment operation of adjusting the duty of the control signal (e.g., DQS) (operation 210) again (Repeat). After the training (operation 212), the controller 160 or the host 110 can perform normal operations (e.g., data input/output operations, etc.) with the memory device 180 (operation 222).

FIG. 4 illustrates a first clock duty control circuit according to an embodiment of the present disclosure. Here, the first clock duty control circuit presents an example in which an analog detector capable of detecting the phase of a clock (CLK_Out) is included.

Referring to FIG. 4, the first clock duty control circuit may include a duty correction circuit (DCC) 402, a detection and sampling unit 404, a counter 406, and an adjustment logic 408.

The duty correction circuit 402 can be configured to receive an input clock Clk_In and generate an output clock Clk_Out. The input clock Clk_In might not have a duty ratio of 5:5 (i.e., 50%). A duty cycle is a numerical value, e.g., expressed as a percentage, representing a ratio of the time that a signal is on (i.e., a logic high level) in a single cycle or period of the signal. The duty cycle of the input clock Clk_In can be less than 50% or greater than 50%. The duty correction circuit 402 can increase or decrease the duty cycle of the input clock Clk_In to generate the output clock Clk_Out having the duty cycle of 50% (i.e., the duty ratio of 5:5).

The detection and sampling unit 404 can be configured to detect an analog phase of the output clock Clk_Out output from the duty correction circuit 402 and sample the detected phase. The counter 406 can be configured to convert the phase sampled by the detection and sampling unit 404 into a digital value.

The adjustment logic 408 can calculate a median value between a power supply voltage VDD and a ground voltage GND. The adjustment logic 408 can calculate an adjustment value (e.g., a delay value) for adjusting the input clock Clk_In in response to the phase and digital value sampled based on the median value (e.g., VDD/2). Based on the adjustment value output from the adjustment logic 408, the duty correction circuit 402 can determine a delay value (e.g., a delay amount) of the input clock Clk_In and change a phase of the input clock Clk_In. Through this scheme, the duty correction circuit 402 can generate the output clock Clk_Out having the duty cycle of 50% (i.e., the duty ratio of 5:5).

The first clock duty control circuit described in FIG. 4 can perform operations for detecting the phase of the output clock Clk_Out through a sensing or detection device, capable of detecting an analog phase of a signal, and calculating an adjustment value for the detected phase of the signal. The first clock duty control circuit including the sensing or detection device can have an advantage of being able to accurately detect the phase of the signal (e.g., an output clock Clk_Out). However, the first clock duty control circuit could spend a relatively great (e.g., at least not a little) processing time or resources on adjusting the duty cycle of the signal (e.g., a clock). A memory system operating at high speed can preferably use an apparatus capable of adjusting the duty cycle or duty ratio of the clock more quickly than the first clock duty control circuit, so as not to deteriorate data input/output (I/O) performance of the memory system.

Hereinafter, a clock duty control circuit capable of eliminating or avoiding duty cycle distortion occurring at a high-speed signal or in data communication process (e.g., a high-speed interface operation of 3.6 Gbps or more) between the controller 160 and the memory device 180 in the memory system 150 capable of storing or outputting voluminous data is presented. In addition, in order to cope with a transmission process (e.g., unmatched DQS feature) in which there is a time difference between the control signal (e.g., DQS, RE) and data (e.g., DQ) to be supported in the memory device 180, the clock duty control circuit could be implemented to support a duty cycle compensation function of the control signal (e.g., DQS, RE), which is used as a data strobe between the controller 160 and the memory device 180, and a transmission delay function through a delay line.

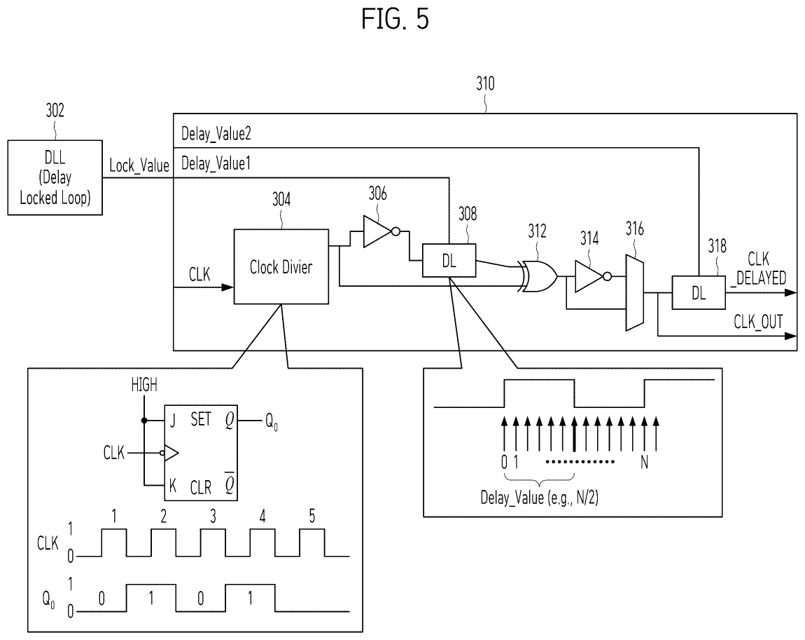

FIG. 5 illustrates a second clock duty control circuit according to an embodiment of the present disclosure.

Referring to FIG. 5, the second clock duty control circuit may include a delay-locked loop (DLL) 302 and a duty correction circuit 310.

The delay locked loop 302 is a type of feedback control system that can be used for various purposes in electronic circuits. The delay locked loop 302 can be used to adjust a frequency and a phase of an input signal to match a frequency and a phase of an output signal to those of the input signal. The delay locked loop 302 can be used for precise clock signal phase adjustment, frequency synthesis, or data transmission timing adjustment in any system. The delay locked loop 302 can be configured to output a locked value Lock_Value which can correspond to a single cycle of the clock CLK.

The clock CLK can be generated internally or received from an outside device. Because of changes in the operating environment (e.g., voltage, temperature, etc.) and the manufacturing process of the semiconductor device or the memory system, unexpected distortion, skew, etc. can occur in a line through which the clock CLK is transmitted or in a circuit that processes the clock CLK. The delay locked loop 302 can output the locked value Lock_Value corresponding to the single cycle of the clock CLK to compensate for the distortion, the skew, etc.

According to an embodiment, the locked value Lock_Value output from the delay locked loop 302 can be input as a first correction value Delay_Value1 of the duty correction circuit 310.

The duty correction circuit 310 can include a clock divider 304 that is configured to divide the input clock CLK in half (i.e., ½). The divider 304 can include a component that transitions an output value based on one of a rising edge and a falling edge of the clock CLK. In an embodiment, in FIG. 5, the divider 304 can transition a logic value of the output Q0 from a logic high level to a logic low level, or vice versa, based on the falling edge of the clock CLK. In another embodiment, the divider 304 can transition a logic value of the output Q0 from a logic high level to a logic low level, or vice versa, based on the rising edge of the clock CLK.

The duty correction circuit 310 can include a first inverter 306 that is configured to invert a divided clock, which is an output of the divider 304.

The duty correction circuit 310 can include a first delay unit 308 that is configured to delay an output of the first inverter 306. The first delay unit 308 can delay the output of the first inverter 306 by a half of the single cycle of the clock CLK in response to the first correction value Delay_Value1. At this time, the half cycle of the clock CLK can vary based on the operating environment (e.g., voltage, temperature, etc.) and the manufacturing process of the semiconductor device or the memory system. The first correction value Delay_Value1 is the locked value Lock_Value corresponding to the single cycle (i.e., 1 cycle) of the clock CLK output from the delay-locked loop 302. The first delay unit 308 can delay the output of the first inverter 306 by half of the first correction value Delay_Value1.

According to an embodiment, the first delay unit 308 can include a plurality of delay elements. Each delay element can include at least one delay cell (e.g., an inverter). For example, the first delay unit 308 can determine N number of delay elements corresponding to the single cycle (i.e., 1 cycle) of the clock CLK based on the first correction value Delay_Value1 among the plurality of delay elements. As a result, each of the N delay elements can have a delay amount equal to N equal parts of the single cycle (i.e., 1 cycle) of the clock CLK. In addition, the first delay unit 308 can select N/2 delay elements corresponding to a half of the single cycle (i.e., 1 cycle) of the clock CLK in response to the first correction value Delay_Value1 to determine the delay amount thereof. The output of the first inverter 306 can be delayed by the N/2 delay elements selected corresponding to a half of the delay amount set in the first delay unit 308.

According to an embodiment, the first delay unit 308 can determine the delay amount by reflecting the delay amount of the first inverter 306.

The duty correction circuit 310 can include a logic gate 312 configured to perform an exclusive OR operation (XOR) on the output of the first delay unit 308 and the output of the divider 304. The result of the exclusive OR (XOR) operation can be a signal having a single cycle corresponding to the locked value Lock_Value output by the delay lock loop 302.

The duty correction circuit 310 can include a second inverter 314 configured to invert the output of the logic gate 312.

The duty correction circuit 310 can include a multiplexer 316 configured to transfer either the output of the logic gate 312 or the output of the second inverter 314. The output of the logic gate 312 and the output of the second inverter 314 can be mutually inverted signals. Among the two signals, one that is good to use or can reduce a delay amount depending on the operating state in the semiconductor device or memory system can be selected. The output of the multiplexer 316 can be determined based on this selection.

The output of the multiplexer 316 can be transmitted to another component as an output clock CLK_OUT whose duty cycle is adjusted to 50%.

According to an embodiment, the semiconductor device or the memory system can use the output clock CLK_OUT after additionally delaying the output clock CLK_OUT. In this case, the duty correction circuit 310 can be further configured to receive a second correction value Delay_value2 for an additional delay amount, delay the output clock CLK_OUT based on the second correction value Delay_value2, and output a delayed clock CLK_DELAYED.

In signal exchange in a high speed interface, a control signal (e.g., a strobe signal) or a clock can be made to maintain a duty ratio of 5:5 in a transmitting device (e.g., the controller 160). A receiving device (e.g., the memory device 180) can transfer data based on the control signal or the clock. However, distortion can often occur due to characteristics of the device during a transmission or reception process of the control signal or the clock through the channel or the receiving device or after the control signal or the clock is input to the receiving device. For these reasons, a duty cycle correction function might be useful in the semiconductor device or the memory system. The ability to restore the duty cycle of the control signal or the clock and the fast speed of restoration could become increasingly critical or important as an operating speed of the semiconductor device or the memory system increases. Further, based on a protocol for signal exchange in a high speed interface, the duty cycle correction function could be considered prerequisite for data communication.

A system on chip (SoC) fabricated based on a silicon substrate can have differences due to a process skew of the process equipment (FAB) from the manufacturing process, and changes occur according to the operating environment due to temperature and voltage changes that occur during use of the SoC after being manufactured as a product. Accordingly, a value preset to have a duty ratio of 5:5, which is the delay amount of the first delay unit 308, may need to be adjusted based on the aforementioned differences and changes. If such adjustment is not made, when the duty ratio is adjusted based on the preset value, issues can occur in performance or inconvenience in control of the SoC (e.g., the semiconductor device or the memory system).

In order to solve the issues, the second clock duty control circuit according to one embodiment of the present disclosure can be implemented using digital operation logic, unlike a conventional analog sensing or detection scheme. The second clock duty control circuit can use one cycle of the clock detected and determined by the delay locked loop (DLL), so that skews and changes in the process, voltage, and temperature (PVT) could be less affected. Through these schemes, the second clock duty control circuit can restore the duty ratio of the clock or the control signal to converge to 5:5. Further, as compared with the conventional analog sensing or detection scheme, the second clock duty control circuit can achieve immediate or very fast restoration due to characteristics implemented with digital operation logic.

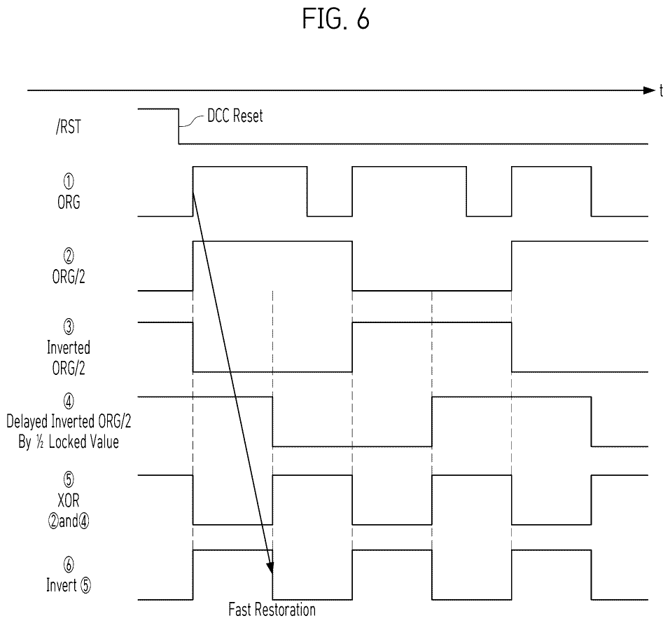

FIG. 6 illustrates an operation method for a clock duty control circuit according to an embodiment of the present disclosure.

Referring to FIG. 6, when a reset signal (/RST) can be activated to a logic low level, a clock duty control circuit (DCC) can be reset.

In a first operation (\textcircled{1}), the clock duty control circuit (DCC) can receive a clock signal ORG. Here, the clock signal ORG might not have a duty ratio of 5:5.

In a second operation (\textcircled{2}), the clock duty control circuit (DCC) can divide the clock signal by ½ to generate a ½-divided clock signal ORG/2. According to an embodiment, the ½-divided clock signal can be generated based on a rising edge of the clock signal ORG.

In a third operation (\textcircled{3}), the clock duty control circuit (DCC) can invert the ½-divided clock signal ORG/2 to generate an inverted ½-divided clock signal (Inverted ORG/2).

In a fourth operation (\textcircled{4}), the clock duty control circuit (DCC) can delay the inverted ½ divided clock signal (Inverted ORG/2) by half of the locked value (½ Locked Value).

In a fifth operation (\textcircled{5}), the clock duty control circuit (DCC) can perform an exclusive OR (XOR) operation on the ½ divided clock signal ORG/2 generated in the second operation (\textcircled{2}) and the delayed and inverted ½ divided clock signal generated in the fourth operation (\textcircled{4}). Through the fifth operation (\textcircled{5}), the clock duty control circuit (DCC) can generate a clock signal having a duty ratio of 5:5.

In a sixth operation (\textcircled{6}), the clock duty control circuit (DCC) can invert the clock signal generated in the fifth operation (\textcircled{5}).

A clock duty control circuit according to an embodiment of the present disclosure can adjust the duty ratio of the clock signal through logic operations, so that the time required for restoration could be very short (Fast Restoration). According to an embodiment, a signal whose duty cycle is adjusted or restored could be output within a single cycle or period before the clock signal ORG.

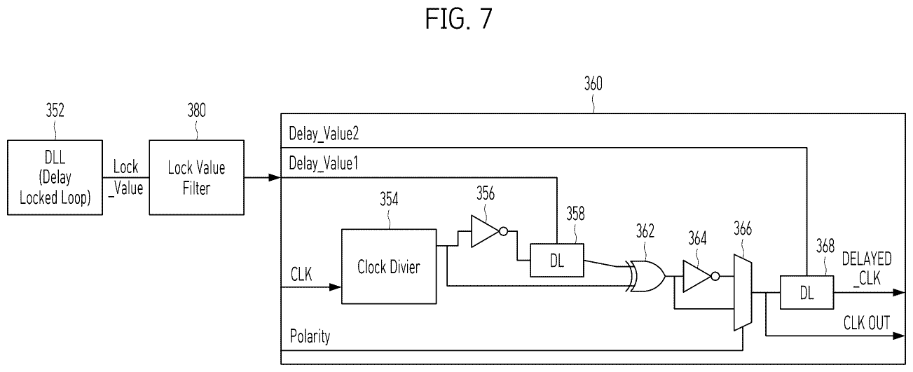

FIG. 7 illustrates a third clock duty control circuit according to an embodiment of the present disclosure. The third clock duty control circuit illustrated in FIG. 7 is similar to the second clock duty control circuit illustrated in FIG. 5.

Referring to FIG. 7, a delay locked loop (DLL) 352 and a lock value filter 380 can be configured to measure a single cycle of the clock CLK input during the operations of the semiconductor device or the memory system, and output the value of the measured cycle as a locked value. To avoid or remove abrupt changes in the locked value, the lock value filter 380 can be configured to perform a filtering process for the locked value. A clock divider 354 is configured to divide the input clock CLK, i.e., a clock requiring duty cycle correction, in half. A ½-speed clock can be generated based on the first inverter 356 configured to invert the clock and the first delay line 358 configured to delay an inverted clock. In addition, the original 1-speed clock could be restored by the exclusive OR (XOR) operation performed through a logic gate 362. The polarity of the clock to be output can be selected using a second inverter 364 and a multiplexer 366. A clock delayed by a preset amount compared to the original clock could be output through a second delay line 368.

Unlike the second clock duty control circuit of FIG. 5, the third clock duty control circuit can include a lock value filter 380. The delay-locked loop DLL can continuously monitor the clock CLK and continuously output a locked value Lock_Value. At this time, filtering can be performed to mitigate sudden changes in the use of the corresponding value which is continuously output. For example, because the locked value that deviates from a preset deviation or range has a high possibility of error, the lock value filter 380 could not be used to restore the duty cycle of the clock CLK.

According to an embodiment, the lock value filter 380 can be configured to calculate an average for the locked values based on a time axis (e.g., a preset time range) and output the average to the duty correction circuit 360 in order to mitigate malfunction due to an error in the locked value that is continuously measured in the delay locked loop DLL. Through this, the duty correction circuit (DCC) 360 in the third clock duty control circuit can adaptively track and reflect a delay amount of the first delay unit 358 based on changes in the process, voltage, and temperature (PVT) of the semiconductor device or the memory system. Further, a delay amount of the second delay unit 368 for reflecting an additionally set delay amount could also be determined based on the correction values output from the delay lock loop (DLL) 352 and the lock value filter 380.

As described above, characteristics and operational changes of semiconductor devices or memory systems occur based on the process, voltage, and temperature conditions. Particularly, the occurrence may be particularly greater in an area related to the clock. The clock duty control circuit according to one embodiment of the present disclosure can actively or adaptively track the locked value fluctuated or changed based on changes in the process, voltage, and temperature (PVT) during operations of the semiconductor devices, as compared with a scheme adjusting a duty cycle with a preset delay value by rote. As a result, the clock or the control signal used in the semiconductor devices or memory systems can continuously keep a 5:5 duty cycle independent of the surrounding environmental changes.

Further, unlike an apparatus adapting a conventional analog detection scheme, a clock duty control circuit according to an embodiment of the present disclosure can use a divider configured to divide a clock in half through several logical operations and a delay unit having a delay amount that adaptively reflects a value corresponding to a half-cycle of the clock, to generate a control signal (or the clock) having a duty cycle of 50%. In addition, a clock duty control circuit according to an embodiment of the present disclosure can use a delay locked loop (DLL) configured to continuously monitor a clock cycle changed according to a change in voltage and temperature (VT) during operations of the semiconductor devices or the memory systems. Further, the clock duty control circuit can use a duty correction circuit (DCC) configured to determine a half-period delay value based on a value obtained by filtering locked values output from the delay-locked loop (DLL).

As above described, a memory device or a memory system according to one embodiment of the present disclosure can maintain a constant duty ratio of a clock to reduce an error that might occur in a procedure of transferring and receiving data or signals even in a change in the operating environment.

Further, a duty correction circuit according to an embodiment of the present disclosure can include a digital logic that operates based on a digital delay value to simplify an internal configuration and improve a duty correction or restoration speed of a clock.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods or operations of the computer, processor, controller, or other signal processing device, are described in detail, the code or instructions for implementing the operations of the method embodiments may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, generators, logic, interfaces, decoders, drivers, and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, generators, logic, interfaces, decoders, drivers, and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, generators, logic, interfaces, decoders, drivers, and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods or operations of the computer, processor, microprocessor, controller, or other signal processing device, are described in detail, the code or instructions for implementing the operations of the method embodiments may transform the computer, processor, controller, or other signal processing device into a special-purpose processor for performing the methods described herein.

While the embodiments of the present disclosure have been illustrated and described with respect to the specific embodiments, it will be apparent to those skilled in the art in light of the present disclosure that various changes and modifications may be made without departing from the field and scope of the present disclosure as defined in the following claims. Furthermore, the embodiments may be combined to form additional embodiments.

What is claimed is:

1. A semiconductor device comprising:
a delay locked loop (DLL) configured to output a first correction value corresponding to a single cycle of a clock; and
a duty correction circuit configured to divide the clock in half, delay a divided clock by a delay value corresponding to a half cycle of the clock to generate a delayed clock, and generate an adjusted clock having a duty ratio of 5:5 based on the divided clock and the delayed clock,
wherein the delay value is adjusted or changed based on the first correction value.

2. The semiconductor device according to claim 1, wherein the delay locked loop is configured to detect a delay of the clock within the semiconductor device based on at least one of changes in an operational environment of the semiconductor device, including power supply and temperature, and changes in a manufacturing process, and to output the first correction value corresponding to the single cycle of the clock.

3. The semiconductor device according to claim 2, wherein the duty correction circuit comprises a divider configured to select one of a rising edge and a falling edge of the clock such that an output value of the divider transitions from a logic high level to a logic low level or from the logic low level to the logic high level based on a selected edge.

4. The semiconductor device according to claim 2, wherein the duty correction circuit comprises a first delay unit comprising N number of delay elements, where N is a positive integer, wherein each of the delay elements has a delay value corresponding to 1/N of the single cycle of the clock, and
by a delay element selected from among the N number of delay elements based on a half of the first correction value.

5. The semiconductor device according to claim 4, wherein the duty correction circuit comprises a first inverter configured to invert the divided clock and transfer an inverted and divided clock to the first delay unit.

6. The semiconductor device according to claim 5, wherein the first delay unit is configured to determine the delay value corresponding to a value obtained by subtracting a delay value of the first inverter from a half of the first correction value.

7. The semiconductor device according to claim 1, wherein the duty correction circuit comprises:
a first logic gate configured to perform an exclusive OR (XOR) operation on the divided clock, and the delayed clock;
a second inverter configured to invert an output of the first logic gate; and
a multiplexer configured to selectively output one of the output of the first logic gate and an output of the second inverter.

8. The semiconductor device according to claim 7, wherein the duty correction circuit further comprises a second delay unit configured to delay an output of the multiplexer based on a second correction value of the delay locked loop and output a delayed output.

9. The semiconductor device according to claim 1, further comprising:
a fixed value filter configured to calculate an average value for first correction values continuously output from the delay locked loop and transmit the average value to the first delay unit.

10. The semiconductor device according to claim 9, wherein the fixed value filter is configured to calculate the average value for values belonging to a preset deviation among the first correction values.

11. A memory system comprising:
at least one memory device; and
a controller coupled to the at least one memory device and configured to adjust a duty ratio of a clock to generate an adjusted clock when power is supplied and perform a read or write training based on the adjusted clock,
wherein the controller comprises:
a delay-locked loop (DLL) configured to output a first correction value corresponding to a single cycle of the clock; and
a duty correction circuit configured to divide the clock in half to generate a divided clock, delay the divided clock by a delay value corresponding to a half cycle of the clock to generate a delayed clock, and generate an adjusted clock having the duty ratio of 5:5 based on the divided clock and the delayed clock.

12. The memory system according to claim 11, wherein the delay value is adjusted or changed based on the first correction value.

13. The memory system according to claim 12, wherein the delay locked loop is configured to detect a delay of the clock within the memory system based on at least one of changes in an operational environment of the memory system, including power supply and temperature, and changes in a manufacturing process, and to output the first correction value corresponding to the single cycle of the clock.

14. The memory system according to claim 13, wherein the duty correction circuit comprises a divider configured to select one of a rising edge and a falling edge of the clock such that an output value of the divider transitions from a logic high level to a logic low level or from the logic low level to the logic high level based on a selected edge.

15. The memory system according to claim 13, wherein the duty correction circuit comprises a first delay unit comprising N number of delay elements, where N is positive integer, wherein each of the delay elements has a delay value corresponding to 1/N of the single cycle of the clock, and
wherein the first delay unit is configured to delay the divided clock by a delay element selected from among the N number of delay elements based on a half of the first correction value.

16. The memory system according to claim 12, wherein the duty correction circuit comprises a first inverter configured to invert the divided clock and transfer an inverted and divided clock to the first delay unit.

17. The memory system according to claim 16, wherein the first delay unit is configured to determine the delay value corresponding to a value obtained by subtracting a delay value of the first inverter from a half of the first correction value.

18. The memory system according to claim 11, wherein the duty correction circuit comprises:
a first logic gate configured to perform an exclusive OR (XOR) operation on the divided clock, and the delayed clock;
a second inverter configured to invert an output of the first logic gate; and
a multiplexer configured to selectively output one of the output of the first logic gate and an output of the second inverter.

19. The memory system according to claim 11, wherein the controller further comprises:
a fixed value filter configured to calculate an average value for the first correction value continuously output from the delay locked loop (DLL) and transmit the average value to the first delay unit.

20. A semiconductor device comprising:
a delay locked loop (DLL) configured to output a first correction value corresponding to a single cycle of a clock; and
a duty correction circuit, without a phase detection device for detecting a phase of the clock, configured to divide the clock in half to generate a divided clock, delay the divided clock by a delay value corresponding to a half cycle of the clock to generate a delayed clock, and generate an adjusted clock having a duty ratio of 5:5 based on the divided clock and the delayed clock.
